(19) United States
(12) Patent Application Publication
(10) Pub. No.: US 2019/0378724 A1
(43) Pub. Date: Dec. 12, 2019

(54) ETCHING METHOD AND ETCHING APPARATUS

(71) Applicant: TOKYO ELECTRON LIMITED, Tokyo (JP)

(72) Inventors: Satoshi TODA, Nirasaki City (JP); Satoru KIKUSHIMA, Nirasaki City (JP); Ken NAKAGOMI, Nirasaki City (JP); Yoshie OZAWA, Nirasaki City (JP); Jun LIN, Nirasaki City (JP)

(21) Appl. No.: 16/434,843

(22) Filed: Jun. 7, 2019

(30) Foreign Application Priority Data
Jun. 8, 2018 (JP) 2018-110555

(51) Int. Cl. H01L 21/311; H01L 21/67

(52) U.S. Cl. CPC H01L 21/31116; H01L 21/67069

(57) ABSTRACT

There is provided an etching method which includes: providing a substrate inside a chamber, the substrate including a silicon oxide-based material and other material, the silicon oxide-based material including an etching target portion having a width of 10 nm or less and an aspect ratio of 10 or more; and selectively etching the etching target portion with respect to the other material by supplying an HF gas and an OH-containing gas to the substrate.

### CROSS-REFERENCE TO RELATED APPLICATION

This application is based upon and claims the benefit of priority from Japanese Patent Application No. 2018-110555, filed on Jun. 8, 2018, the entire contents of which are incorporated herein by reference.

### TECHNICAL FIELD

The present disclosure relates to an etching method and an etching apparatus.

### BACKGROUND

Patent Documents 1 and 2 disclose a chemical oxide removal (COR) process of removing a silicon oxide film in a chemical manner.

### PRIOR ART DOCUMENTS

### Patent Documents

Patent Document 1: Japanese laid-open publication No. 2005-039185

Patent Document 2: Japanese laid-open publication No. 2008-160000

### SUMMARY

Some embodiments of the present disclosure provide an etching method and an etching apparatus which are capable of chemically etching a material on a substrate with high selectivity without etching inhibition which may be caused by a reaction product.

According to an embodiment of the present disclosure, there is provided an etching method which includes: providing a substrate inside a chamber, the substrate including a silicon oxide-based material and other material, the silicon oxide-based material including an etching target portion having a width of 10 nm or less and an aspect ratio of 10 or more; and selectively etching the etching target portion with respect to the other material by supplying an HF gas and an OH-containing gas to the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart showing an etching method according to a first embodiment.

FIG. 2 is a sectional view showing a structural example of a substrate used for etching.

FIG. 3 is a sectional view showing a state in which an SiO₂ film of the substrate having a structure shown in FIG. 2 is etched using an HF gas and an NH₃ gas.

FIG. 4 is a sectional view showing a state in which an SiO₂ film of the substrate having a structure shown in FIG. 2 is etched using an HF gas and an H₂O gas.

FIG. 5 is a view showing a relationship between a concentration of C in an SiOCₓN film and an etched amount when the SiOCₓN film is etched by an HF gas and an H₂O gas.

FIG. 6 is a flowchart showing an etching method according to a second embodiment.

FIG. 7 is a flowchart showing an etching method according to a third embodiment.

FIG. 8 is a schematic configuration view showing an example of a processing system used to carry out the etching methods according to the above embodiments.

FIG. 9 is a sectional view showing an etching apparatus provided in the processing system shown in FIG. 8.

FIG. 10 is a view showing a relationship between a time period and an etched depth when etching is performed in case A and case B in Experimental example 1.

FIG. 11 is a view showing a relationship between a temperature and etching rates of an SiO₂ film and an SiN film, and a relationship between a temperature and an etching selectivity of an SiO₂ film to an SiN film in Experimental example 2.

FIG. 12 is a view showing the relationship between a time period and an etched amount when etching an SiO₂ film, an SiCN film and an SiOCN film in case C (HF gas/H₂O gas) in Experimental example 3.

FIG. 13 is a view showing the relationship between a time period and an etched amount when etching an SiO₂ film, an SiCN film and an SiOCN film in case D (HF gas/NH₃ gas) in Experimental example 3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <History and Overview>

First, the history and overview of an etching method according to an embodiment of the present disclosure will be described. As disclosed in Patent Documents 1 and 2, the chemical oxide removal (COR) process of chemically etching a silicon oxide-based material such as an SiO₂ film or the like uses HF gas and NH₃ gas as an etching gas. In these techniques, the HF gas and the NH₃ gas are adsorbed onto the SiO₂ film and are reacted with SiO₂ to form (NH₄)₂SiF₆ (ammonium fluorosilicate (AFS)), which is a solid reaction product, as shown in the following formula (1). In a subsequent process, the AFS is sublimated by heating.

6HF+6NH₃+SiO₂→2H₂O+4NH₃+(NH₄)₂SiF₆ (1)

Meanwhile, in a semiconductor device, a silicon oxide-based material often coexists with various films such as SiN, SiCN, metal and the like. Thus, it is required to etch the silicon oxide-based material with high etching selectivity with respect to these films. For this reason, there is a tendency to perform etching at a low temperature etching in which the above-mentioned etching reaction proceeds with ease.

However, in such a low-temperature etching, when a width of a silicon oxide-based material to be etched is narrow and an aspect ratio thereof is high, specifically, when the width is 10 nm or less and the aspect ratio is 10 or more, the progress of etching may be inhibited by the generation of AFS which is a reaction product. Etching stop may occur when the progress of etching is inhibited. In addition, the presence of AFS may degrade the etching selectivity with respect to other film.

Therefore, in an embodiment of the present disclosure, there is performed an etching method (removal method) which includes providing a substrate inside a chamber, and supplying an HF gas and an OH-containing gas toward the substrate to etch an etching target portion of a silicon oxide-based material included in the substrate. The substrate includes other material in addition to the silicon oxide-based material. The etching target portion of the silicon oxide-based material has a width of 10 nm or less and an aspect ratio of 10 or more.

A reaction formula in a case of etching SiO₂ by using the HF gas and a gas containing an OH group (OH group-containing gas) such as a water vapor (H₂O gas) or the like as an etching gas is represented by the following formula (2).

4HF+H₂O+SiO₂→SiF₄T+3H₂O (2)

That is to say, theoretically, no solid reaction product is generated which inhibits etching as in the case of using the HF gas and the NH₃ gas. Therefore, even when the width of the etching target portion is narrow and the aspect ratio is high, the silicon oxide-based material can be etched without etching inhibition which may be caused by a reaction product. This makes it possible to etch the silicon oxide-based material with high throughput without occurrence of the etching stop. In addition, the absence of AFS as a reaction product suppresses the reaction of the silicon oxide-based material with other film such as an SiN film or the like, thus enhancing the etching selectivity with respect to other film.

### SPECIFIC EMBODIMENTS

Next, specific embodiments will be described.

### First Embodiment

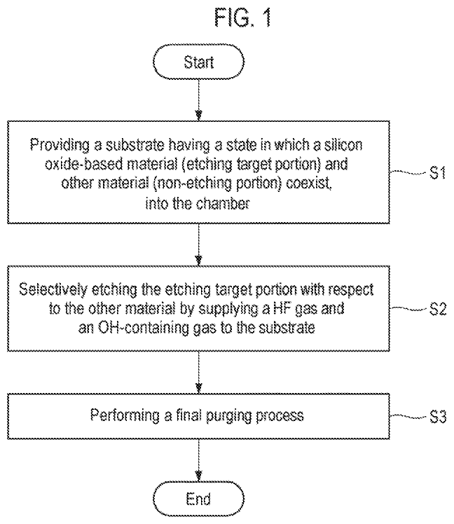

First, a first embodiment, which is a basic etching method, will be described. FIG. 1 is a flowchart showing an etching method according to a first embodiment. A substrate in which a silicon oxide-based material (etching target portion) and other material (non-etching portion) coexist is loaded into a chamber (in step S1).

The substrate may be, but is not particularly limited thereto, a semiconductor wafer represented by a silicon wafer. The silicon oxide-based material is typically SiO₂ and may be a material containing silicon and oxygen, such as SiOCN or the like. The silicon oxide-based material is typically a film. The SiO₂ film used as a silicon oxide-based material may be a thermal oxide film or a film formed by a chemical vapor deposition method (CVD method) or an atomic layer deposition method (ALD method). An example of the SiO₂ film formed by the CVD method or the ALD method may include a film formed by using SiH₄ or aminosilane as a Si precursor.

Other examples of the silicon oxide-based material may include SiN, SiCN, a metal-based material, and Si. These materials are typically films. The metal-based material is a metal or a metal compound, and may be HfOₓ. Ti, Ta or the like. In addition, both the etching target portion and the non-etching portion may be silicon oxide-based materials. As an example, the etching target portion may be SiO₂, and other material may be SiOCN or the like.

A silicon oxide-based material such as SiO₂ or the like which is the etching target portion has a narrow width and a high aspect ratio. Specifically, the width of the silicon oxide-based material is 10 nm or less and the aspect ratio thereof is 10 or more.

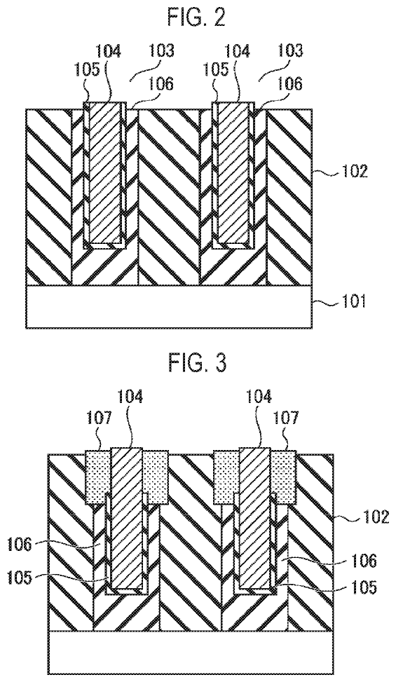

The substrate may have a structure as shown in FIG. 2, for example. In the example of FIG. 2, the substrate has a structure in which an insulating film 102 is formed on a Si base 101 and a recess 103 is formed in the insulating film 102. A metal film (or a Si film) 104 is inserted into the recess 103. An SiCN (or SiCON) film 105 is formed on a surface of the metal film 104. The insulating film 102 has a sidewall made of a SiN film. An SiO₂ film 106 for forming an air gap is formed between the insulating film 102 (the SiN film serving as a sidewall) and the SiCN film 105 in the recess 103. The width of the SiO₂ film as an etching target portion is 10 nm, and the aspect ratio thereof is 10 or more.

Subsequently, HF gas and OH-containing gas are supplied to the substrate to selectively etch the etching target portion with respect to other material (in step S2).

This etching is performed in a state in which the substrate is disposed inside the chamber. The HF gas and the OH-containing gas supplied to the substrate inside the chamber are adsorbed onto a front surface of the substrate to promote an etching reaction. Among these gases, the HF gas exerts an etching action, and the OH-containing gas exerts a catalytic action. The catalytic action is considered to be the action of an OH group.

As the OH-containing gas, a water vapor and an alcohol gas may be suitably used. The alcohol gas may be a monohydric alcohol but is not particularly limited thereto. Examples of the monohydric alcohol may include methanol (CH₃OH), ethanol (C₂H₅OH), propanol (C₃H₇OH) and butanol (C₄H₉OH). At least one of them may be suitably used.

In addition to the HF gas and the OH-containing gas, an inert gas may be supplied as a dilution gas. As the inert gas, an N₂ gas or a noble gas may be used. An Ar gas may be used as the noble gas. Other noble gases such as a He gas and the like may be used. The inert gas may also be used as a purge gas for purging the interior of the chamber.

A temperature of the substrate at the time of carrying out step S2 may be 50 degrees C. or less, specifically in a range from −20 to 20 degrees C. This is because the lower the temperature, the higher the selectivity of the etching target film to the coexisting non-etching target film, and because the lower the temperature, the smaller the damage to the semiconductor element. In addition, an etching rate of the silicon oxide-based material increases rapidly when the substrate temperature is 10 degrees C. or less, and increases more rapidly when the substrate temperature is 5 degrees C. or less. On the other hand, other material such as SiN or the like is hardly etched. Therefore, when the substrate temperature is 10 degrees C. or less, specifically 5 degrees C. or less, a large selectivity of 50 or more, specifically 200 or more may be obtained. From this point of view, the substrate temperature may fall within a range from −20 to 10 degrees C., ultimately a range from −20 to 5 degrees C.

An internal pressure of the chamber when performing step S2 may fall within a range of 100 mTorr to 100 Torr (13.3 to 13,330 Pa). The internal pressure depends on the substrate temperature. The higher the substrate temperature, the higher the internal pressure. When the substrate temperature falls within a range of −20 to 20 degrees C., the internal pressure may fall within a range of 2 to 10 Torr (266 to 1,333 Pa).

When the OH-containing gas is a water vapor, a volume ratio (flow rate ratio) G_{OH}/HF of the OH-containing gas (G_{OH}) to the HF gas may be 1.5 or less, specifically in a range of 0.5 to 1.5. The richer the gas containing OH groups in a molecule, the more uniformly the etching can proceed. The actual flow rate depends on an apparatus. As an example, the flow rate of the HF gas may fall within a range of 100 to 800 sccm, and the flow rate of the gas containing OH groups in a molecule may fall within a range of 100 to 800 sccm.

In step S2, the OH-containing gas (for example, the water vapor) may be supplied before starting the supply of the HF gas. This is because, by initially supplying a gas containing OH groups in a molecule, which serves as a catalyst, and causing the gas to be adsorbed onto the substrate, it is possible to perform uniform etching without generating local etching (pit) or the like by the HF gas supplied subsequently.

Furthermore, in step S2, the HF gas and the gas containing OH groups in a molecule may be supplied in a state in which they are not mixed with each other in a gas supply part such as a gas supply pipe, a shower head or the like before reaching the chamber, i.e., in a post-mix state. In the case of a so-called premix condition in which the gases are mixed with each other in a gas supply pipe or a shower head, there is a concern that the gases may be liquefied under a high pressure environment.

After the etching of step S2 is performed, the supply of the HF gas and the gas containing OH groups in a molecule is stopped, a final purging process for the interior of the chamber is performed (in step S3), and the process is ended.

The purging process of step S3 may be performed by evacuating the interior of the chamber. During the evacuation, NH₃ gas may be supplied into the chamber. By the purging process of step S3, it is possible to remove a fluorine-based residue remaining in the chamber. After the purging process, if necessary, the substrate may be subjected to a heat treatment for residue removal.

When the SiO₂ film 106 having the structure of FIG. 2 is etched by using an HF gas and NH₃ gas as an etching gas as in Patent Documents 1 and 2, AFS 107 as a reaction product may be produced in an etched portion as shown in FIG. 3. When a width of the SiO₂ film 106 is 10 nm or less and an aspect ratio is 10 or more, the AFS as a reaction product may cause etching inhibition in the middle of the etching and may cause etching stop. In addition, the SiN film constituting the sidewall of the insulating film 102 may be etched by the AFS. This degrades the selectivity.

On the other hand, in the present embodiment, the etching target portion of the silicon oxide-based film is etched using the HF gas and the OH-containing gas. Therefore, even if the width of the etching target portion is 10 nm or less and the aspect ratio thereof is 10 or more, the etching target portion of the silicon oxide-based material can be etched with high selectivity to other coexisting material (non-etching portion) without etching inhibition which may be caused by the reaction product.

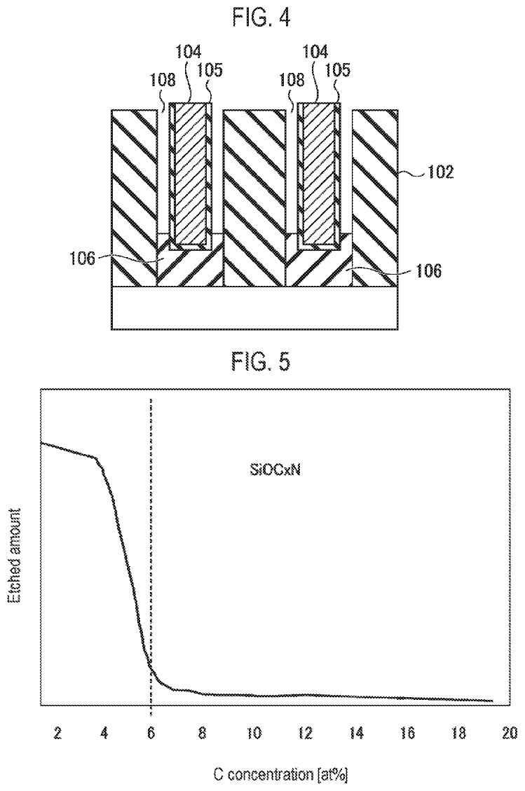

For example, when etching the SiO₂ film 106 of the substrate shown in FIG. 2, even if the width of the SiO₂ film 106 is 10 nm or less and the aspect ratio thereof is 10 or more, as shown in FIG. 4, it is possible to form a desired air gap 108 without causing etching inhibition. In addition, the SiO₂ film 106 can be etched with high selectivity with almost no etching of the SiN film of the sidewall of the insulating film 102.

In the present embodiment, as described above, the other material (non-etching portion) coexisting with the silicon oxide-based material (etching target portion) may be at least one selected from SiN, SiCN, a metal-based material (for example, HfOₓ, Ti, Ta, etc.) and Si. The etching of the silicon oxide-based material can be realized with high selectivity of 50 or more, ultimately 200 or more, to the other material. For example, when the etching target material is an SiO₂ film and the other material is a SiN film, it is possible to achieve an etching selectivity of 50 or more, ultimately 200 or more.

In some embodiments, both the etching target portion and the non-etching portion may be silicon oxide-based materials. For example, even in the case where the silicon oxide-based material as an etching target portion is SiO₂ and the other material as a non-etching portion is SiOCN or the like, it is possible to etch SiO₂ with high selectivity.

### Second Embodiment

Next, a second embodiment will be described. In this embodiment, steps S1 to S3 are generally performed as in the first embodiment.

In step S1, a substrate which includes a first SiOCN material and a second SiOCN material having a concentration of C higher than that in the first SiOCN material is used. The substrate is provided inside a chamber. The first SiOCN material is an etching target material, and the second SiOCN material is other material. The first and second SiOCN materials are typically SiOCN films.

In step S2, HF gas and OH-containing gas are supplied to the substrate to selectively etch the first SiOCN material with respect to the second SiOCN material. That is to say, when the etching target material is an SiOCN material, even if the other material is also the same SiOCN material, it is possible to perform selective etching by adjusting the concentration of C.

FIG. 5 is a view showing a relationship between the concentration of C in the SiOCₓN film and an etched amount of the SiOCₓN film when the SiOCₓN film is etched by an HF gas and an H₂O gas. The SiOCN film is a film formed by CVD. As shown in FIG. 5, when the concentration of C is in the range of 1 to 6 at %, the sensitivity of the etched amount to the concentration of C is very high, and the etched amount is sharply reduced along with the increase of C. On the other hand, when the concentration of C exceeds 6 at %, the etched amount is hardly changed.

Therefore, if the concentration of C in the first SiOCN material as an etching target material is 1 to 6 at % and the concentration of C in the second SiOCN material as other material is higher than that in the first SiOCN material, it is possible to etch the first SiOCN material with high selectivity. In particular, when the concentration of C in the first SiOCN material is 2 at % or less and the concentration of C in the second SiOCN material exceeds 6 at %, the selectivity becomes a value exceeding 30.

SiOCN is suitable as a liner material for a conductor. SiON has been used as the liner material. SiON has a high dielectric constant and a high parasitic capacitance. On the other hand, the parasitic capacitance can be reduced by doping SiON with C to form SiOCN. In addition, SiOCN has a high strength and a high insulation property. For this reason. SiOCN is suitable as a liner material of a conductor.

By using SiOCN as both the remaining material such as a liner material or the like and the etching target material, when forming a film with these materials, it is possible to perform a process with the same kind of gas in a film forming step. For this reason, it is not necessary to process these materials in different chambers, which makes it possible to simplify the process.

In addition, when the remaining material is SiOCN and the etching target material is a material such as SiO₂ or the like, which constitute different films, defects may possibly occur between the films. However, by using the same kind of material as both the remaining material and the etching target material, it is possible to suppress defects which may occur between the films.

In the present embodiment, the above effects can be obtained regardless of the shape of the first SiOCN material which is the etching target material. However, the same effects as those of the first embodiment can be obtained when the width of the etching target portion of the first SiOCN material as the etching target material is 10 nm or less and the aspect ratio thereof is 10 or more. That is to say, in the case where the HF gas and the NH₃ gas are used as the etching gas, when the width of the etching target portion of the first SiOCN material is 10 nm or less and the aspect ratio thereof is 10 or more, etching inhibition is caused by a reaction product. On the other hand, by using the HF gas and the OH-containing gas, even if the width of the etching target portion of the first SiOCN material is 10 nm or less and the aspect ratio thereof is 10 or more, it is possible to selectively etch the first SiOCN material without causing an etching inhibition. That is to say, the etching target portion (first SiOCN material) having a width of 10 nm or less and an aspect ratio of 10 or more is selectively removed.

In the present embodiment, steps S2 and S3 may be performed in the same manner as in the first embodiment.

### Third Embodiment

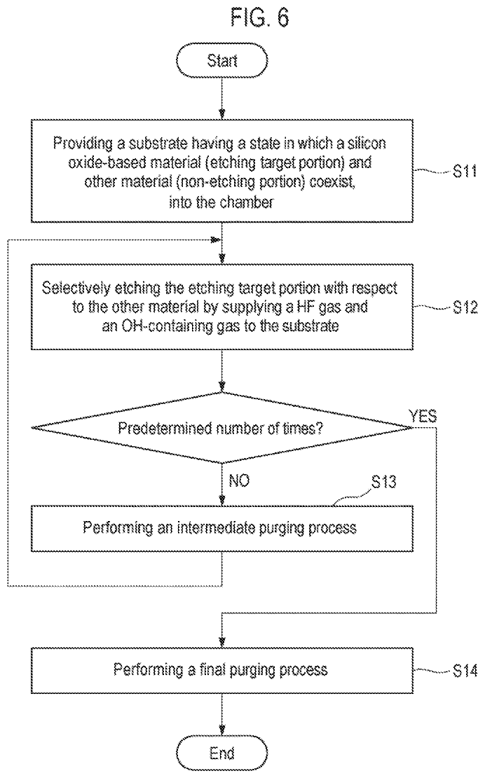

Next, a third embodiment will be described. FIG. 6 is a flowchart showing an etching method according to the third embodiment. First, as in step S1 of the first embodiment, a substrate having a state in which a silicon oxide-based material (etching target portion) and other material (non-etching portion) coexist is provided inside a chamber (step S11). As in the first embodiment, the etching target portion of the silicon oxide-based material as an etching target material has a width of 10 nm or less and an aspect ratio of 10 or more.

Subsequently, as in step S2 of the first embodiment, HF gas and OH-containing gas are supplied to the substrate to selectively etch the etching target portion with respect to other material (step S12). Conditions applied at this time are the same as those of step S2 of the first embodiment. However, in step S12, unlike in step S2, the etching of the etching target portion is stopped halfway.

Subsequently, the supply of the HF gas and the OH-containing gas is stopped, and an intermediate purging process of purging the interior of the chamber is performed (step S13). The intermediate purging process may be performed by evacuating the interior of the chamber. In addition, if a residue exists in a narrow etching space formed after etching a silicon oxide-based material having a high aspect ratio, it is difficult to remove the residue. Therefore, a purge gas may be supplied into the chamber in the middle of evacuation. As the purge gas, an inert gas such an N₂ gas, an Ar gas or the like is suitable.

After the intermediate purging process, the etching of the silicon oxide-based material in step S12 is performed again.

When the number of execution times of step S12 reaches a predetermined number of times, a final purging process of finally purging the interior of the chamber is performed (step S14). Then, the process is completed.

The final purging process of step S14 may be performed by evacuating the chamber. During the evacuation. NH₃ gas may be supplied into the chamber. This makes it possible to remove a fluorine-based residue remaining in the chamber. After the final purging process, if necessary, the substrate may be subjected to a heat treatment for residue removal (step S15).

As described above, the third embodiment performs a cyclic etching in which an etching process is repeated a predetermined number of times, i.e., twice or more. This makes it possible to obtain effects which are more advantageous than the effects obtained when the etching is performed once as in the first embodiment. That is to say, in the case of performing the etching once, the HF gas as the etching gas makes contact with other non-etching material for a long period of time. Thus, there is a problem that the surface of the film to be etched is roughened or scraped. However, by repeating the etching process a plurality of times while performing the intermediate purging process between the etching processes, it is possible to shorten the period in which the HF gas makes contact with the non-etching target film. Therefore, the aforementioned problem does not occur. In addition, an etching rate can be increased by repeating the etching process a plurality of times.

The cyclic etching of the third embodiment may be applied to the second embodiment.

### Fourth Embodiment

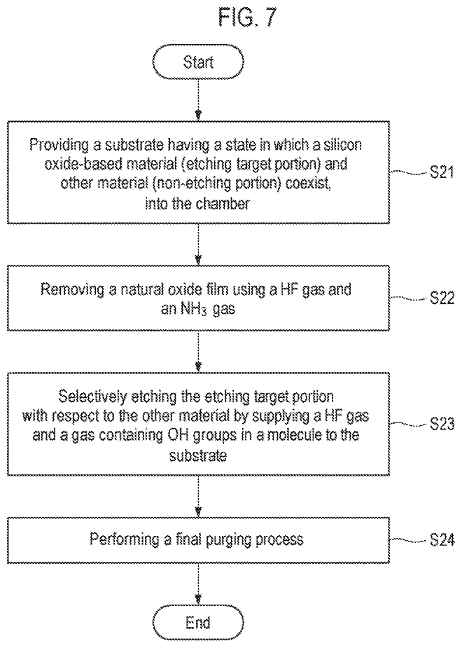

Next, a fourth embodiment will be described. FIG. 7 is a flowchart showing an etching method according to the fourth embodiment. First, as in step S1 of the first embodiment, a substrate having a state in which a silicon oxide-based material (etching target portion) and other material (non-etching portion) coexist is prepared (step S21). As in the first embodiment, the etching target portion of the silicon oxide-based material as an etching target material has a width of 10 nm or less and an aspect ratio of 10 or more.

Subsequently, a natural oxide film on the front surface of the substrate is removed using HF gas and NH₃ gas (step S22). This process includes a step of generating AFS by supplying HF gas and NH₃ gas to the substrate inside the chamber, causing the HF gas and the NH₃ gas to be adsorbed onto the front surface of the substrate and allowing the HF gas and the NH₃ gas to react with the natural oxide film (SiO₂ film) on the front surface of the substrate, and a step of sublimating the AFS by heating.

The process using the HF gas and the NH₃ gas is performed under the conditions that a temperature of the substrate is 10 to 75 degrees C., an internal pressure of chamber is 0.1 to 3 mTorr (13.3 to 400 Pa), a flow rate of the HF gas is 100 to 500 sccm and a flow rate of the NH₃ gas is 100 to 500 sccm.

Subsequently, as in step S2 of the first embodiment, HF gas and OH-containing gas are supplied to the substrate, from which the natural oxide film has been removed, to selectively etch the etching target portion with respect to other material (step S23). Conditions at this time are the same as those of step S2 of the first embodiment.

After performing the etching of step S23, the supply of the HF gas and the OH-containing gas is stopped, and a final purging process of finally purging the interior of the chamber is performed (step S24). Then, the process is completed.

The final purging process of step S24 may be performed by evacuating the interior of the chamber. During the evacuation. NH₃ gas may be supplied into the chamber. This makes it possible to remove a fluorine-based residue remaining in the chamber. After the final purging process, if necessary, the substrate may be subjected to a heat treatment for residue removal.

In the present embodiment, after the removal of the natural oxide film in step S22, as in the third embodiment, a cyclic etching may be performed in which an etching process is repeated a predetermined number of times, i.e., twice or more.

As described above, in the fourth embodiment, after the natural oxide film is initially removed using the HF gas and the NH₃ gas, the gases are changed to the HF gas and the OH-containing gas to etch the silicon oxide-based material.

As described above, the etching using the HF gas and the OH-containing gas does not cause etching inhibition even when the etching target portion having a width of 10 nm or less and an aspect ratio of 10 or more is etched. In addition, etching can be performed with high selectivity to other coexisting material such as SiN, a metal-based material or the like.

However, the etching using the HF gas and the OH-containing gas has a long incubation time. Thus, it requires time to remove an oxide film such as a natural oxide film or the like formed on the entire surface of the substrate, resulting in a decrease in throughput.

On the other hand, the etching using the HF gas and the NH₃ gas may suffer from etching inhibition and selectivity reduction at the time of etching the etching target portion having a narrow width and a high aspect ratio as described above, but does not suffer from such a problem at the time of removing the natural oxide film. That is to say, at the time of removing the natural oxide film, the etching in a narrow space portion is not necessary, and the AFS generation reaction proceeds at a high rate due to the HF gas and the NH₃ gas. In addition, at the time of removing the natural oxide film, it is not necessary to consider the selectivity to other material.

Accordingly, in the present embodiment, the processes from the removal of the natural oxide film to the etching of the silicon oxide-based film formed on the substrate may be performed with high throughput and with high selectivity.

The fourth embodiment may be applied to the second embodiment.

### <Processing System>

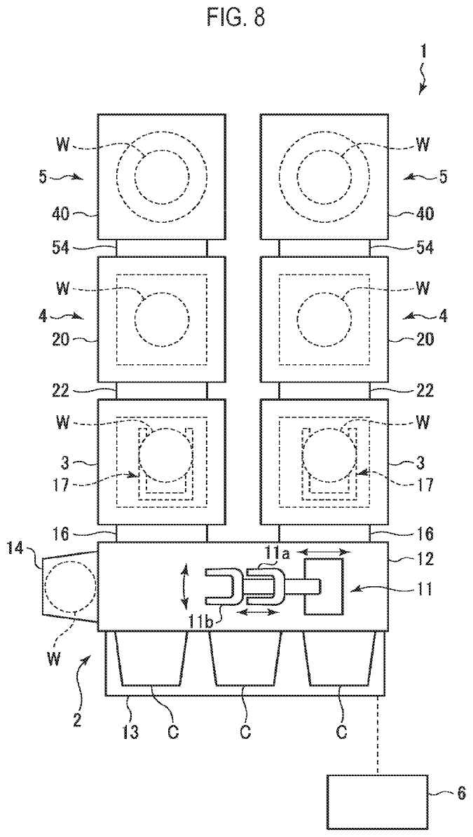

Next, an example of a processing system used to perform the etching method according to the embodiments will be described. FIG. 8 is a schematic block diagram showing an example of such a processing system. The processing system 1 is used for etching a semiconductor wafer (hereinafter simply referred to as a wafer) W which is a substrate in which a silicon oxide-based material as an etching target material and other material coexist as described above.

The processing system 1 includes a loading/unloading part 2, two load lock chambers (L/L) 3, two heat treatment apparatuses 4, two etching apparatuses 5 and a controller 6.

The loading/unloading part 2 is used for loading and unloading the wafer W. The loading/unloading part 2 includes a transfer chamber (L/M) 12 in which a first wafer transfer mechanism 11 for transferring the wafer W is provided. The first wafer transfer mechanism 11 includes two transfer arms 11a and 11b for holding the wafer W in a substantially horizontal posture. A stage 13 is provided on one side of the transfer chamber 12 in the longitudinal direction. For example, three carriers C each capable of storing a plurality of wafers W side by side may be connected to the stage 13. Furthermore, an orienter 14 configured to perform alignment of the wafer W by rotating the wafer W and optically obtaining an amount of eccentricity of the wafer W is provided adjacent to the transfer chamber 12.

In the loading/unloading part 2, the wafer W is transferred to a desired position by being linearly moved in a substantially horizontal plane and moved up and down with the driving of the first wafer transfer mechanism 11 while being held by the transfer arm 11a or 11b. The wafer W is loaded and unloaded by moving the transfer arm 11a or 11b toward and away from the carrier C on the stage 13, the orienter 14 and the lock chambers 3, respectively.

The two load lock chambers (L/L) 3 are provided adjacent to the loading/unloading part 2. Each of the load lock chambers 3 is coupled to the transfer chamber 12 with a gate valve 16 interposed between the load lock chamber 3 and the transfer chamber 12. In each of the load lock chambers 3, there is provided a second wafer transfer mechanism 17 for transferring the wafer W. Furthermore, the load lock chamber 3 is configured so that it can be evacuated to a predetermined degree of vacuum.

The second wafer transfer mechanism 17 has an articulated arm structure and includes a pick for holding the wafer W in a substantially horizontal posture. In the second wafer transfer mechanism 17, the pick is positioned inside the load lock chamber 3 with the articulated arm kept in a contracted state. By extending the articulated arm, the pick can reach the heat treatment apparatus 4. By further extending the articulated arm, the pick can reach the etching apparatus 5. Accordingly, the wafer W can be transferred between the load lock chamber 3, the heat treatment apparatus 4 and the etching apparatus 5.

Each of the two heat treatment apparatuses 4 is configured to perform a heat treatment on the wafer. The two heat treatment apparatuses 4 are provided adjacent to the two load lock chambers (L/L) 3, respectively. The heat treatment apparatus 4 includes a chamber 20 which can be evacuated. The wafer W is mounted on a stage provided in the chamber 20. The stage is provided with a heating mechanism by which the wafer W mounted on the stage is heated to a predetermined temperature. An inert gas such as an N₂ gas or the like is introduced into the chamber 20. The wafer W is subjected to a heat treatment at a predetermined temperature while maintaining the chamber 20 in a depressurized inert gas atmosphere.

Each of the two etching apparatuses 5 are configured to perform a chemical etching on the wafer W. The two etching apparatuses 5 are provided adjacent to the two heat treatment apparatuses 4, respectively. Details of the etching apparatus 5 will be described later.

The gate valve 16 is provided between the transfer chamber 12 and the load lock chamber (L/L) 3. Furthermore, a gate valve 22 is provided between the load lock chamber (L/L) 3 and the heat treatment apparatus 4. Moreover, a gate valve 54 is provided between the heat treatment apparatus 4 and the etching apparatus 5.

The controller 6 is formed of a computer, and includes a main controller having a CPU, an input device (keyboard, mouse, etc.), an output device (printer, etc.), a display device (display, etc.), and a memory device (memory medium). The main controller controls the operation of each component of the processing system 1. The control of each component by the main controller is executed according to a process recipe which is a control program stored in a memory medium (a hard disk, an optical disk, a semiconductor memory, etc.) incorporated in the memory device.

In the processing system 1 configured as above, the plurality of wafers W is loaded into the processing system 1 while being stored in the carrier C. In the processing system 1, one of the wafers W is transferred from the carrier C of the loading/unloading part 2 to the load lock chamber 3 by the transfer arm 11a or 11b of the first wafer transfer mechanism 11 in a state in which the gate valve 16 disposed at the atmospheric side is opened. The wafer W is delivered on the pick of the second wafer transfer mechanism 17 in the load lock chamber 3.

Thereafter, the atmospheric-side gate valve 16 is closed, and the interior of the load lock chamber 3 is evacuated. Then, the gate valve 54 is opened, and the pick is extended to the etching apparatus 5 to transfer the wafer W to the etching apparatus 5.

Thereafter, the pick is returned to the load lock chamber 3, the gate valve 54 is closed, and the etching process of the silicon oxide-based material is performed in the etching apparatus 5 according to the etching method of the embodiment described above.

During the etching process or after the etching process, the gate valves 22 and 54 are opened, and the wafer W subjected to the etching process is transferred to the heat treatment apparatus 4 by the pick of the second wafer transfer mechanism 17. Then, a reaction product such as AFS or the like or an etching residue is heated and removed by the heat treatment apparatus 4.

After the heat treatment in the heat treatment apparatus 4 is completed, if necessary, the wafer W is transferred to the etching apparatus 5 by the second wafer transfer mechanism 17, and the etching process is continued.

Then, the wafer W subjected to the heat treatment or the etching process is transferred to the load lock chamber 3, and the load lock chamber 3 is returned to the air atmosphere. Thereafter, the wafer W in the load lock chamber 3 is returned to the carrier C by one of the transfer arms 11a and 11b of the first wafer transfer mechanism 11. As a result, the processing of one wafer is completed.

### <Etching Apparatus>

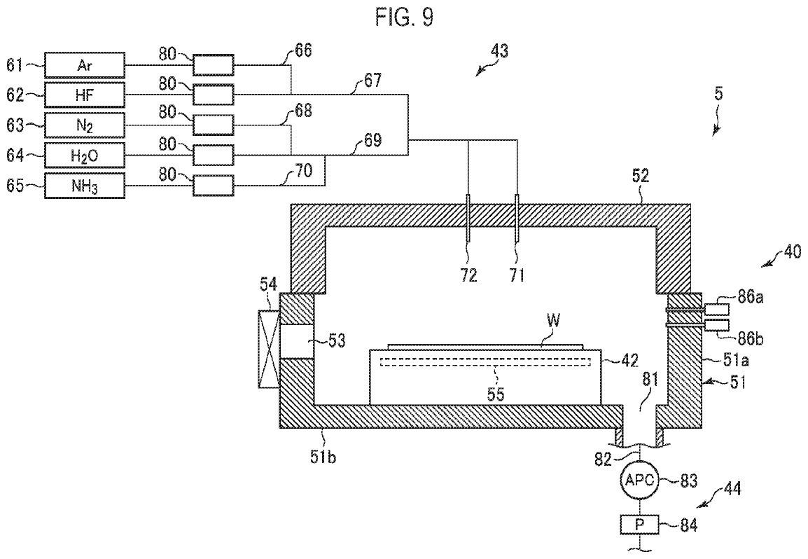

Next, the etching apparatus 5 will be described in detail. FIG. 9 is a sectional view showing the etching apparatus 5. As shown in FIG. 9, the etching apparatus 5 includes a chamber 40 having a sealed structure. Inside the chamber 40, there is provided a stage 42 on which the wafer W is mounted in a substantially horizontal posture. The etching apparatus 5 further includes a gas supply mechanism 43 configured to supply an etching gas into the chamber 40 and an exhaust mechanism 44 configured to exhaust the interior of the chamber 40.

The chamber 40 includes a chamber body 51 and a lid 52. The chamber body 51 has a substantially cylindrical sidewall portion 51a and a bottom portion 51b. An upper portion of the chamber body 51 is opened. The opening is closed by the lid 52. The sidewall portion 51a and the lid 52 are sealed by a sealing member (not shown) to ensure the airtightness in the chamber 40. A first gas introduction nozzle 71 and a second gas introduction nozzle 72 are inserted into the chamber 40 from above through a top wall of the lid 52.

A loading/unloading port 53 through which the wafer W is loaded into and unloaded from the chamber 20 of the heat treatment apparatus 4 is formed in the sidewall portion 51a. The loading/unloading port 53 can be opened and closed by the gate valve 54.

The stage 42 is substantially circular in a plan view and is fixed to the bottom portion 51b of the chamber 40. Inside the stage 42, there is provided a temperature adjuster 55 for adjusting a temperature of the stage 42. The temperature adjuster 55 may include a pipeline through which a temperature adjusting medium (e.g., water or the like) circulates. As heat exchange is performed with the temperature adjusting medium flowing through such a pipeline, the temperature of the stage 42 is adjusted so that the temperature of the wafer W mounted on the stage 42 is controlled.

The gas supply mechanism 43 includes an Ar gas source 61, an HF gas source 62, an N₂ gas source 63, an H₂O gas source 64, and an NH₃ gas source 65 for supplying an NH₃ gas. The Ar gas source 61 and the N₂ gas source 63 are configured to supply N₂ gas and Ar gas as an inert gas having a function as a carrier gas, in addition to a dilution gas and a purge gas. In some embodiments, gases supplied from both the Ar gas source 61 and the N₂ gas source 63 may be Ar gas or N₂ gas. As described above, the inert gas is not limited to the Ar gas and the N₂ gas. The H₂O gas source 64 is configured to supply a water vapor (H₂O gas) as an OH-containing gas.

One ends of first to fifth gas supply pipes 66 to 70 are connected to the gas sources 61 to 65, respectively. The other end of the second gas supply pipe 67 connected to the HF gas source 62 is connected to the first gas introduction nozzle 71. The other end of the first gas supply pipe 66 connected to the Ar gas source 61 is connected to the second gas supply pipe 67. The other end of the fourth gas supply pipe 69 connected to the H₂O gas source 64 is connected to the second gas introduction nozzle 72. The other end of the third gas supply pipe 68 connected to the N₂ gas source 63 and the other end of the fifth gas supply pipe 70 connected to the NH₃ gas source 65 are connected to the fourth gas supply pipe 69. Therefore, the HF gas is supplied into the chamber 40 without being mixed with the H₂O gas and the NH₃ gas in the pipe.

Each of the first to fifth gas supply pipes 66 to 70 is provided with a flow rate controller 80 which perform a flow path opening/closing operation and a flow rate control operation. The flow rate controller 80 may include an opening/closing valve and a mass flow controller (MFC) or a flow control system (FCS).

A shower head may be provided in an upper portion of the chamber 40, and the gas may be supplied in the form of a shower through the shower head. In this case, a post-mix type shower head in which the HF gas and the H₂O gas are not mixed with each other may be used as the shower head.

The exhaust mechanism 44 includes an exhaust pipe 82 connected to an exhaust port 81 formed in the bottom portion 51b of the chamber 40, an automatic pressure control valve (APC) 83 provided in the exhaust pipe 82 to control an internal pressure of the chamber 40 and a vacuum pump 84 provided in the exhaust pipe 82 to evacuate the interior of the chamber 40.

Two capacitance manometers 86a and 86b as pressure gauges for measuring the internal pressure of the chamber 40 are provided in the sidewall of the chamber 40 so as to be inserted into the chamber 40. The capacitance manometer 86a is used for high pressure, and the capacitance manometer 86b is used for low pressure. In the vicinity of the wafer W mounted on the stage 42, there is provided a temperature sensor (not shown) for detecting a temperature of the wafer W.

Al is used as a material of various components such as the chamber 40 and the stage 42 that constitute the etching apparatus 5. The Al material constituting the chamber 40 may be pure Al or may have an anodized inner surface (an inner surface of the chamber body 51, etc.). On the other hand, a surface of Al constituting the stage 42 is required to have a wear resistance. Therefore, it is preferable to perform an anodizing treatment to form an oxide film (Al₂O₃) having a high wear resistance on the surface.

In the etching apparatus 5 configured as above, the etching methods of the first to fourth embodiments are implemented under the control of the controller 6.

First, the wafer W having a silicon oxide-based film as an etching target film formed thereon is loaded into the chamber 40 and is mounted on the stage 42.

Subsequently, in the case of implementing the etching methods of the first to third embodiments, an H₂O gas or, additionally, Ar gas and N₂ gas as inert gases are supplied into the chamber 40. Thus, the temperature of the wafer W is stabilized, and the internal pressure of the chamber 40 is stabilized at a predetermined pressure. Then, HF gas is introduced into the chamber 40, and the silicon oxide-based material of the wafer W is selectively etched by the HF gas and the H₂O gas. In the case of the third embodiment, a cyclic etching is performed while performing the intermediate purging process between etchings as described above.

In the case of implementing the method of the fourth embodiment, after the wafer W is mounted on the stage 42, NH₃ gas or, additionally, Ar gas and an N₂ gas as inert gases are supplied into the chamber 40. Thus, the temperature of the wafer W is stabilized, and the internal pressure of the chamber 40 is stabilized at a predetermined pressure. Then, HF gas is introduced into the chamber 40, and the HF gas and the NH₃ gas are caused to react with the natural oxide film on the surface of the wafer W to generate AFS which is a reaction product. Thereafter, the wafer W is unloaded from the chamber 40 and the interior of the chamber 40 is purged.

The wafer W unloaded from the chamber 40 is subjected to a heat treatment in the heat treatment apparatus 4 to remove AFS. Then, the wafer W from which AFS has been removed is loaded into the chamber 40 again.

Thereafter, an H₂O gas or, additionally, Ar gas and N₂ gas as inert gases are supplied into the chamber 40 to perform a process of stabilizing the temperature of the wafer W and the internal pressure of the chamber 40. Then, HF gas is introduced into the chamber 40, and the silicon oxide-based material present on the wafer W is selectively etched by the HF gas and the H₂O gas. The etching may be a cyclic etching in which the intermediate purging process is performed between etchings.

In any of the first to fourth embodiments, after completion of the respective etching, the interior of the chamber 40 is purged as described above, and the etching process is ended. After the purging process, if necessary, the wafer W may be transferred to the heat treatment apparatus 4 where the wafer W is subjected to a heat treatment for residue removal.

### EXPERIMENTAL EXAMPLES

Next, experimental examples will be described.

### Experimental Example 1

In this example, a substrate having the structure shown in FIG. 2 was prepared, and the SiO₂ film on the substrate was etched. The SiO₂ film is a film formed by ALD using aminosilane as a silicon precursor. The width of the etched portion was 5 nm, the depth thereof was 70 nm, and the aspect ratio thereof was 12. The etching (case A) using HF gas and water vapor (H₂O gas) used in the embodiments and the etching (case B) using HF gas and NH₃ gas were performed on the substrate, and the relationship between a time period and an etched depth was grasped. In case A, the etching was performed under the conditions that the temperature is −20 to 20 degrees C., the pressure is 2.0 to 10.0 Torr (266 to 1,333 Pa), the flow rate of the HF gas is 100 to 800 sccm, the flow rate of the H₂O gas is 100 to 800 sccm, and the flow rate of the N₂ gas is 100 to 2000 sccm. In case B, the etching was performed under the conditions that the temperature is 10 to 75 degrees C., the pressure is 100 to 3,000 mTorr (13.3 to 400 Pa), the flow rate of the HF gas is 100 to 500 sccm, the flow rate of the NH₃ gas is 100 to 500 sccm, the flow rate of the N₂ gas is 100 to 2,000 sccm, and the flow rate of the Ar gas is 20 to 500 sccm.

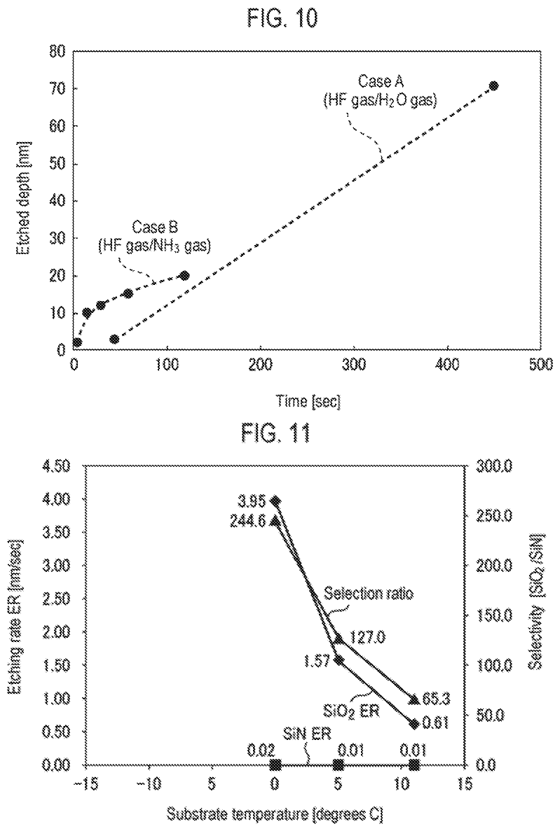

FIG. 10 is a view showing the relationship between the time period and the etched depth when etching is performed in case A and case B. As shown in FIG. 10, in case B where the etching was performed using the HF gas and the NH₃ gas, it can be noted that the etching rate of the SiO₂ film is sharply lowered when the etched depth is around 10 nm, and etching stop occurs at the etched depth of around 20 nm. On the other hand, in case A where the etching was performed using the HF gas and the H₂O gas, it was possible to etch the SiO₂ film to 70 nm without causing etching stop. This is presumably because the reaction product AFS inhibits etching in case B, whereas the reaction product inhibiting etching is not generated in case A.

### Experimental Example 2

In this example, an SiO₂ film and a SiN film were etched by using the HF gas and the water vapor (H₂O gas) used in the embodiments and changing the temperature in the range of 0 degrees C. to 10 degrees C. The SiO₂ film used is a film formed by ALD using aminosilane as a silicon precursor, and the SiN film used is a film formed by CVD using hexachlorodisilane (HCD) as a silicon precursor. Conditions other than the temperature at the time of etching were set such that the pressure is 2.0 to 10.0 Tort (266 to 1,333 Pa), the flow rate of the HF gas is 100 to 800 sccm, and the flow rate of the H₂O gas is 100 to 800 sccm.

FIG. 11 is a view showing the relationship between a temperature and an etching rate of the SiO₂ film and the SiN film, and the relationship between the temperature and an etching selectivity of the SiO₂ film to the SiN film. As shown in FIG. 11, as the temperature decreases, the etching rate of the SiO₂ film and the etching selectivity of the SiO₂ film to the SiN film sharply increase. At 0 degrees C., the etching selectivity of the SiO₂ film to the SiN film is 244.6 which is an extremely high value.

### Experimental Example 3

In this example, samples were prepared in which SiO₂ film, SiCN film having a concentration of C of 8 at % and an SiOCN film having a concentration of C of 5 at % are formed on a substrate, respectively. The SiCN film and the SiOCN film are films formed by CVD. The SiO₂ film is a film formed by ALD using aminosilane as a silicon precursor. The width of the SiO₂ film was 5 nm, the depth thereof was 70 nm, and the aspect ratio thereof was 12. The etching (case C) using HF gas and water vapor (H₂O gas) used in the embodiments and the etching (case D) using HF gas and NH₃ gas were performed on the samples for 45 seconds. The relationship between a time period and an etched amount was grasped with respect to the SiO₂ film, the SiCN film and the SiOCN film. Conditions of case C and case D are the same as those of case A and case B, respectively.

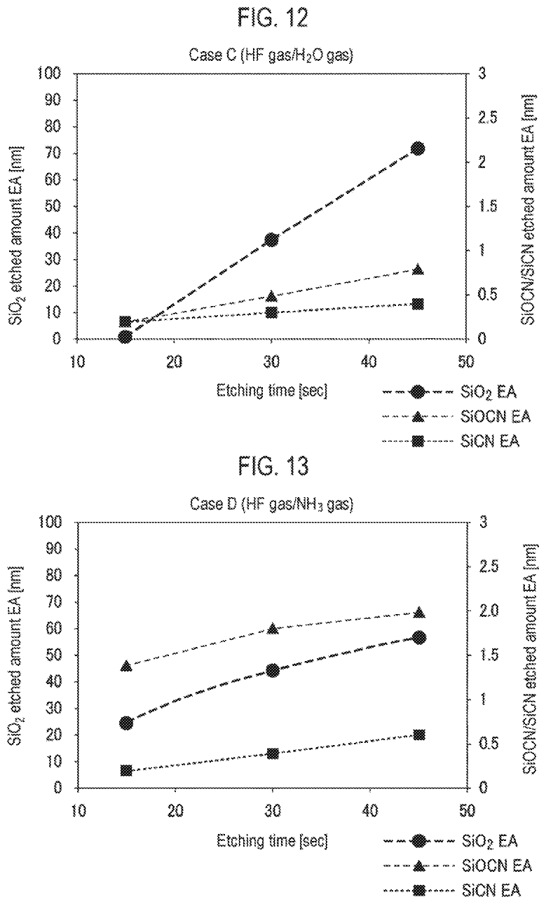

FIG. 12 is a view showing the relationship between the time period and the etched amount when etching the SiO₂ film, the SiCN film and the SiOCN film in case C (HF gas/H₂ gas). FIG. 13 is a view showing the relationship between the time period and the etched amount when etching the SiO₂ film the SiCN film and the SiOCN film in case D (HF gas/NH₃ gas).

As shown in FIG. 12, in case C where the etching was performed using the HF gas and the H₂O gas, the SiO₂ film could be etched to 70 nm at a substantially constant etching rate. In addition, it was confirmed that the etched amounts of the SiCN film and the SiOCN film were small and the SiO₂ film was etched with high selectivity.

On the other hand, as shown in FIG. 13, in case D where the etching was performed using the HF gas and the NH₃ gas, it can be noted that the etching rate of the SiO₂ film is smaller than that in case C, and the etching is further reduced particularly after 30 secs. Furthermore, it can be seen that the etched amount of the SiOCN film is larger than that in case C and the selectivity of the SiO₂ film to the SiOCN film is lower than that in case C.

### OTHER APPLICATIONS

Although embodiments have been described above, it should be appreciated that the embodiments disclosed herein are exemplary and not restrictive in all respects. The embodiments described above may be omitted, substituted or changed in various forms without departing from the scope of the appended claims and the subject matter thereof.

For example, the apparatuses of the above-described embodiments are nothing more than examples, and apparatuses having various configurations may be used. Although there has been described a case where the semiconductor wafer is used as a substrate to be processed, the substrate is not limited to the semiconductor wafer but may be other substrates such as an FPD (flat panel display) substrate represented by a substrate for LCD (liquid crystal display), a ceramic substrate and the like.

According to the present disclosure in some embodiments, it is possible to chemically etch a material on a substrate with high selectivity without etching inhibition which may be caused by a reaction product.

What is claimed is:

1. An etching method, comprising:
providing a substrate inside a chamber, the substrate including a silicon oxide-based material and other material, the silicon oxide-based material including an etching target portion having a width of 10 nm or less and an aspect ratio of 10 or more; and
selectively etching the etching target portion with respect to the other material by supplying an HF gas and an OH-containing gas to the substrate.

2. The method of claim 1, wherein the OH-containing gas is a water vapor or an alcohol gas.

3. The method of claim 1, wherein the other material is at least one selected from SiN, SiCN, a metal-based material, and Si.

4. The method of claim 1, wherein the silicon oxide-based material is SiO₂ and the other material is at least one selected from SiN, SiCN, SiOCN, a metal-based material, and Si.

5. An etching method, comprising:
providing a substrate inside a chamber, the substrate including a first SiOCN material and a second SiOCN material with a higher concentration of C than the first SiOCN material; and
selectively etching the first SiOCN material with respect to the second SiOCN material by supplying an HF gas and an OH-containing gas to the substrate inside the chamber.

6. The method of claim 5, wherein the first SiOCN material includes an etching target portion having a width of 10 nm or less and an aspect ratio of 10 or more, and
wherein the selectively etching includes selectively etching the etching target portion.

7. The method of claim 5, wherein the first SiOCN material has the concentration of C of 1 to 6 at %.

8. The method of claim 5, wherein the first SiOCN material has the concentration of C of 2 at % or less.

9. The method of claim 1, wherein a temperature of the substrate in the selectively etching the etching target portion falls within a range of −20 to 20 degrees C.

10. The method of claim 1, wherein an internal pressure of the chamber in the selectively etching the etching target portion falls within a range of 2 to 10 Torr (266 to 1,333 Pa).

11. The method of claim 1, wherein the HF gas and the OH-containing gas are supplied into the chamber without being mixed with each other.

12. The method of claim 11, wherein the OH-containing gas is supplied before the start of the supply of the HF gas.

13. The method of claim 1, wherein the selectively etching the etching target portion is repeatedly performed,
the method further comprising: performing an intermediate purging process,
wherein the intermediate purging process includes:
exhausting an interior of the chamber: and
supplying a purge gas into the chamber during the exhausting the interior of the chamber.

14. The method of claim 1, further comprising:
removing a natural oxide film from a surface of the substrate using an HF gas and an NH₃ gas, wherein the removing occurs before the selectively etching the etching target portion.

15. The method of claim 1, further comprising:
performing a final purging process after the selectively etching the etching target portion, wherein the final purging process includes:
exhausting an interior of the chamber; and
supplying an NH₃ gas into the chamber during the exhausting the interior of the chamber.

16. The method of claim 5, wherein the selectively etching the etching target portion is repeatedly performed,
the method further comprising: performing an intermediate purging process,
wherein the intermediate purging process includes:
exhausting an interior of the chamber; and
supplying a purge gas into the chamber during the exhausting the interior of the chamber.

17. The method of claim 5, further comprising:
removing a natural oxide film from a surface of the substrate using an HF gas and an NH₃ gas, wherein the removing occurs before the selectively etching the etching target portion.

18. The method of claim 5, further comprising:
performing a final purging process after the selectively etching the etching target portion,
wherein the final purging process includes:
exhausting an interior of the chamber; and
supplying an NH₃ gas into the chamber during the exhausting the interior of the chamber.

19. An etching apparatus, comprising:
a chamber in which a substrate is accommodated;
a stage provided inside the chamber and configured to mount the substrate thereon;
a temperature adjuster configured to adjust a temperature of the substrate mounted on the stage;
a gas supply part configured to supply a gas including an etching gas to the chamber;
an exhausting part configured to exhaust an interior of the chamber; and
a controller configured to control the temperature adjuster, the gas supply part and the exhausting part.
